(19) United States
(12) Patent Application Publication
(10) Pub. No.: US 2017/0164445 A1
(43) Pub. Date: Jun. 8, 2017

(54) Textured Window and Method

(71) Applicant: Rubicon Technology, Inc., Bensenville, IL (US)

(72) Inventor: John P. Ciraldo, Elgin, IL (US)

(21) Appl. No.: 14/957,325

(22) Filed: Dec. 2, 2015

(51) Int. Cl. H05B 33/22; C30B 29/20; C30B 33/08

(52) U.S. Cl. CPC H05B 33/22; C30B 33/08; C30B 29/20

(57) ABSTRACT

A window has a substantially optically transparent substrate, and an aluminum oxide layer supported by the transparent substrate. The aluminum oxide layer has a textured surface. The aluminum oxide layer may include an anisotropically etched polycrystalline aluminum oxide. Alternatively, the aluminum oxide layer may include an anisotropically etched, damaged single-crystal sapphire. Either way, the aluminum oxide layer may include a film formed on the top surface of the substrate. Thus, the textured surface is opposite to that of the top surface of the substrate—they are not adjacent.

### FIELD OF THE INVENTION

Illustrative embodiments of the invention generally relate to protective windows for devices and, more particularly, illustrative embodiments relate to windows configured to mitigate damage caused by normal and aggressive use.

### BACKGROUND OF THE INVENTION

Smartphones seem to be everywhere—they are used in schools, businesses, the government, and in the military. Smartphones used for these applications have a common problem; namely, their displays often scratch and crack. In fact, this problem extends beyond smartphones. A wide variety of other devices, such as computer display devices, smartwatches, flip-phones, and tablet computers, to name a few, have the same problem.

### SUMMARY OF VARIOUS EMBODIMENTS

In accordance with one embodiment of the invention, a window has a substantially optically transparent substrate, and an aluminum oxide layer supported by the transparent substrate. The aluminum oxide layer has a textured surface.

The aluminum oxide layer preferably includes an anisotropically etched polycrystalline aluminum oxide. Alternatively, the aluminum oxide layer may include an anisotropically etched, damaged single-crystal sapphire. Either way, the aluminum oxide layer may include a film formed on the top surface of the substrate. Thus, the textured surface is opposite to that of the top surface of the substrate—they are not adjacent. The substrate may be formed from any of a variety of different materials, such as one or more of glass, quartz, single-crystal sapphire, and yttria-stabilized zirconia.

The textured surface preferably has an RMS surface roughness that is related to the wavelength of the light transmitted through the window. In illustrative embodiments, the RMS surface roughness may be a minimum of about twenty-five percent of the lowest wavelength of the range of light passing through the window. For example, if that range of wavelengths includes the visible spectrum, then the RMS surface roughness may have a minimum RMS surface roughness of about 75 nanometers or 100 nanometers.

Accordingly, to effectively mitigate reflections, the aluminum oxide layer may form a planar surface sufficiently textured to scatter at least a portion of light incident on the textured planar surface. That aluminum oxide may be in the form of sapphire or other related material. In some embodiments, the aluminum oxide may be embodied as a film having a thickness of between about 300 nanometers and about 2 microns.

In accordance with another embodiment, a device includes a light source, a substantially optically transparent substrate, and an aluminum oxide layer supported by the transparent substrate. The aluminum oxide layer has a textured surface to mitigate reflections.

In this latter embodiment, the aluminum oxide layer preferably is positioned close to the light source. To that end, the substrate is between the light source and the aluminum oxide layer. As such, the aluminum oxide layer preferably is no more than about 1.5 millimeters (e.g., about 1.0 millimeter) from the light source, which may include one or more of light emitting diodes (“LEDs”) or liquid crystals.

In accordance with other embodiments, a method of producing a window forms a layer of aluminum oxide on an optically transparent substrate, and covers at least a portion of the aluminum oxide layer in an etchant. Next, the method removes at least some of the etchant (preferably substantially all of the etchant) from the aluminum oxide layer. The aluminum oxide layer thus has a textured surface after removing at least some of the etchant.

Among other ways, this method may cover the aluminum oxide layer by immersing at least the portion of the substrate and the aluminum oxide layer in a bath of the etchant. Indeed, those skilled in the art may select any of a variety of etchants. For example, the etchant may be a base etchant that does not appreciably react with the substrate. Acid etchant also should suffice. In either case, the etchant may anisotropically etch the aluminum oxide layer to form the textured surface.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically shows a smartphone that may incorporate a window configured in accordance with illustrative embodiments of the invention.

FIG. 1B schematically shows an exploded view of the window and display of the smartphone in FIG. 1A.

FIG. 2A schematically shows a plan view of a window that may be configured in accordance with illustrative embodiments of the invention.

FIG. 2B schematically shows a cross-sectional view of the window of FIG. 2A across line B-B.

FIG. 3 shows a general process for forming a window configured in accordance with illustrative embodiments of the invention.

FIG. 4A schematically shows a cross-sectional view of the substrate used to form a window in accordance with illustrative embodiments of the invention. This figure shows the window at step 300 of the process of FIG. 3.

FIG. 4B schematically shows a cross-sectional view of the window of FIGS. 2A and 2B before it is textured. This figure shows the window at step 302 of the process of FIG. 3.

FIG. 5 schematically shows a cross-sectional view of a system for texturing a window in accordance with illustrative embodiments of the invention.

### DESCRIPTION OF ILLUSTRATIVE EMBODIMENTS

In illustrative embodiments, a protective window for use in any of a wide variety of devices, such as a smartphone, is substantially scratch resistant and yet, minimizes reflections on its face. To that end, the window has a layer of textured aluminum oxide on an optically transparent substrate. The textured aluminum oxide protects the window from scratches and other similar damage while reducing the noted reflections. Details of illustrative embodiments are discussed below.

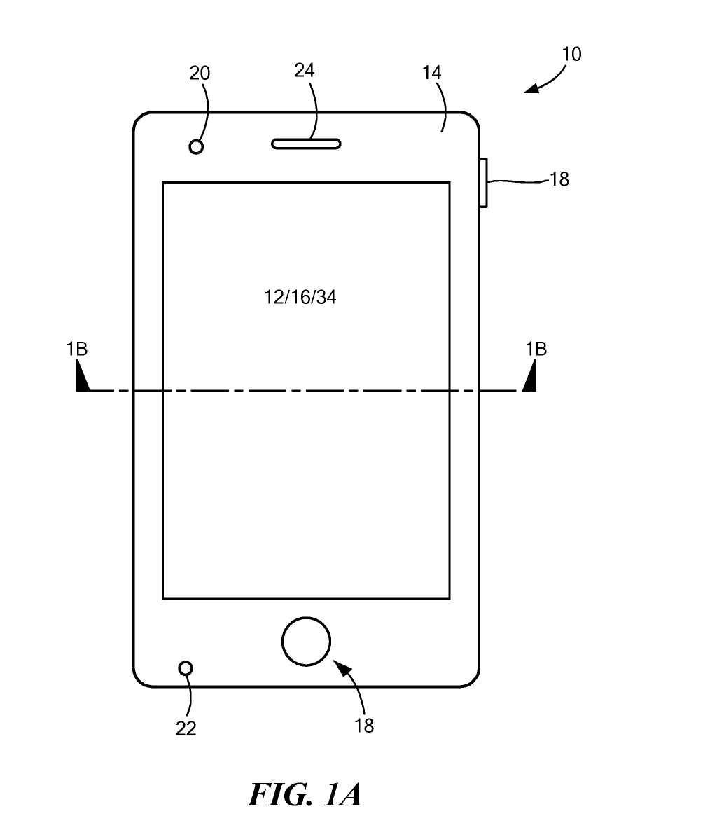

FIG. 1A schematically shows a plan view of a smartphone 10 that may use a protective window (hereinafter “window 12”) configured in accordance with illustrative embodiments of the invention. Like many other smartphones, the smartphone 10 in FIG. 1A has a body 14 containing a touch sensitive display 16 (also referred to as a “touchscreen”) for producing graphical images. As known by those skilled in the art, the touch sensitive display 16 also acts as an input device that responds to direct contact. That contact typically capacitively or piezoelectrically couples with circuitry on a printed circuit board 28 (FIG. 1B, discussed below) contained within the body 14 to cause a responsive action. For example, a user may touch a button shown on the display 16 with a stylus or their finger to initiate a telephone call, send an email, or listen to music stored in memory.

In addition to the display 16, the smartphone 10 has a number of other input and output components. For example, the smartphone 10 has at least two input buttons 18, a video aperture 20 for directing visual input to a still and/or video camera, an audio aperture 22 for directing audio signals to a microphone, and an opening 24 for a speaker to deliver sound. Those skilled in the art can have more or less functionality as desired by the specific application.

To receive input and produce visual output, the display 16 is directly exposed to the environment. As such, it can receive a great deal of wear and tear over its lifetime, which undesirably can cause scratches, breaks, dents, and other damage. To minimize this problem, the display 16 has a relatively strong protective window 12 covering it sensitive portions. FIG. 1B depicts an example of such a window 12 by schematically showing an exploded, cross- sectional view of the smartphone 10 of FIG. 1A across line B-B. Specifically, FIG. 1B shows the body 14, which forms an open chamber 26 that receives the display 16, a printed circuit board 28 (e.g., a flex circuit) having circuitry configured to control both the display 16 and other functions of the device, and a battery 30 that energizes both the display 16 and circuitry on the printed circuit board 28.

In this example, the display 16 has two primary parts: an active display portion 32 with the image producing and stimulus/input functionality, and a protective window 12 configured in accordance with illustrative embodiments of the invention to protect the active display portion 32. Any of a variety of commonly known display technologies can implement the display portion 32. For example, the display portion 32 can have well-known liquid crystal display components, which may include various filters, polarizers, backlights, and a liquid crystal layer. As another example, the display portion 32 can have a matrix of well-known light emitting diodes (LEDs), which each have cathodes, electrodes, and active layers (e.g., an active-matrix organic LED).

Without the protective window 12, normal use will likely damage the display portion 32. Those skilled in the art thus have used protective windows to cover the display portion 32. Accordingly, to protect the display portion 32, the window should be very hard and robust. The inventor recognized, however, that prior art windows that were hard and robust suffer from a significant design flaw. Specifically, while they may have provided reasonable protection for the display portion 32, those hard and robust prior art windows often have a substantial glare problem. In other words, those prior art windows reflect environmental light, making it more difficult to see the indicia produced by the display 16. The art responded to this created problem by increasing the brightness of the display 16. Undesirably, turning up the brightness drains the battery 30, thus adding to already difficult power consumption problems.

The inventor recognized these problems and, after experimentation, discovered that the window itself could be processed and configured to protect the display portion 32, while mitigating/minimizing glare. In fact, the inventor accomplished these competing goals with an elegant, relatively low cost solution.

To that end, the window 12 has a hard, durable textured top surface 34 configured to substantially scatter incident light from the environment. In illustrative embodiments, although the protective layer 38 may reflect some light, the total amount of reflected light is much less than if it were not textured in the desired manner. Accordingly, rather than seeing a glare from the window 12, the user may see a dull reflection, or only minimally perceive a reflection at all. The textured top surface 34 thus substantially scatters environmental light incident on its surface, effectively mitigating reflections.

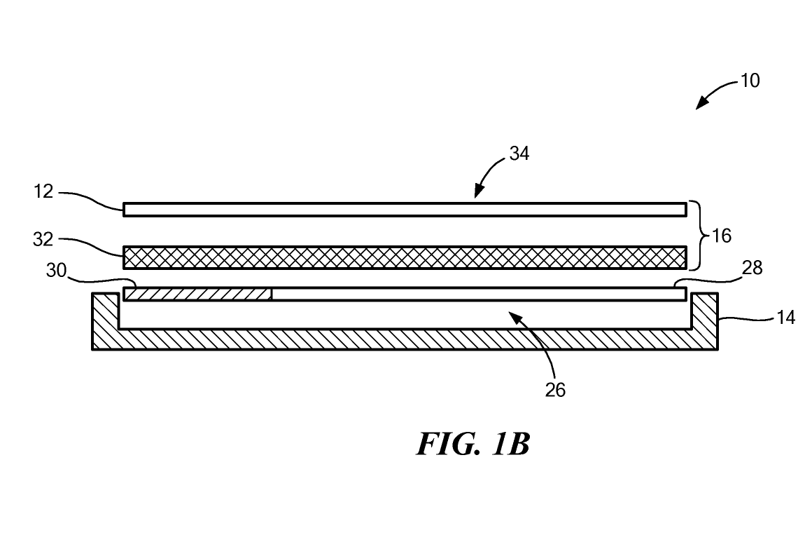

More specifically, FIG. 2A schematically shows a plan view of the window 12 configured in accordance with illustrative embodiments of the invention. To show more details on the top surface 34, FIG. 2B schematically shows a cross-sectional view of the window 12 across line 2B-2B of FIG. 2A. As shown, the window 12 includes a substantially optically transparent substrate 36 supporting an externally facing protective layer 38 that is both durable and antireflective (i.e., the protective layer 38 mitigates reflections). When secured to the smartphone 10, the substrate 36 is between the display portion 32 and the protective layer 38. As such, the protective layer 38 directly contacts the environment, such as the air, people's fingers, styluses, the inside of a person's purse or pocket, and inadvertent contacts (e.g., rocks and corners of furniture when in a person's pocket).

As a part of the smartphone 10, the window 12 should generally freely transmit light in the visible spectrum. Accordingly, the optically transparent nature of the substrate 36 should permit a substantial majority of visible light to pass from the display portion 32 to the user. In other words, the substrate 36 should no more than minimally scatter certain incident light directed from the display portion 32, through its body, and to the environment. For example, the substrate 36 may be considered optically transparent if it transmits at least 80 percent of incident light through its body. Indeed, it is expected that such light may be generated primarily from the display portion 32 (e.g., the LEDs or liquid crystals).

Alternative embodiments, however, may transmit light outside of the visual spectrum. For example, the window 12 may be used with a device that generates certain infrared waves that are not in the visible spectrum. In that case, the window 12 may be tuned to optimally transmit those appropriate light waves.

Those skilled in the art can select the substrate 36 based upon the application. Among other things, the substrate 36 can be formed from glass, quartz, single-crystal sapphire, and yttria-stabilized zirconia. Of course, those skilled in the art can form the substrate 36 from a number of other materials. Accordingly, discussion of specific materials is illustrative and not intended to limit various other embodiments of the invention.

The protective layer 38 serves at least two overarching purposes:
to protect the display portion 32 of the display 16, and
to protect the substrate 36 so that it does not impede device functionality.

Accordingly, those skilled in the art select the protective layer 38 from a material that is sufficiently hard to withstand the rigors of a given application. When used with a smartphone 10, for example, the protective layer 38 preferably is formed from a material that is durable enough to withstand the day-to-day wear and tear of a typical smartphone 10. The inventors recognized that aluminum oxide (also known as “alumina”) appropriately met this requirement for the smartphone 10 application, as well as a wide variety of other applications. In addition to having higher thermal conductivity and dielectric properties, aluminum oxide also is a high strength, hard, and wear resistant material. Accordingly, the protective layer 38 may be formed from a single layer of a variant of aluminum oxide, such as gamma-phase aluminum oxide.

Specifically, as known by those skilled in the art, aluminum oxide (Al₂O₃) is a chemical compound or ceramic formed from aluminum and oxygen. It takes on many forms, including both crystalline and non-crystalline forms. Of course, illustrative embodiments use aluminum oxide in its crystalline form. For example, although it may be used in its single crystal/monocrystalline form, the aluminum oxide preferably is used for the protective layer 38 in its polycrystalline form. As such, the textured surface preferably is anisotropically etched (discussed below).

In related embodiments, the aluminum oxide may form the mineral corundum, commonly known as sapphire. Accordingly, the protective layer 38 also may take on the form of polycrystalline or single crystalline sapphire. Moreover, the aluminum oxide preferably is configured to be substantially oleophobic and thus, reduces smudges that may accumulate on its surface from oils in user's hands, and other oils that may contact its face. For example, the structure may be processed to have a random topology, or the surface may be processed to control surface chemistry to enhance oleophobicity. To those ends, the protective layer 38 may be hydrophobic. Specifically, the water contact angle of the protective layer 38 may be greater than or equal to about 90 degrees.

While it has appropriate strength and generally sufficient optically transmissive properties for the display portion 32, aluminum oxide still has the other noted problem—it still is reflective of environmental light. For example, if used as part of a smartphone window without an additional anti-glare layer or coating, aluminum oxide may produce a glare that is distracting to the user. One potential solution to this problem is, as noted, to apply an additional anti-glare layer or coating over the aluminum oxide layer. Undesirably, in addition to increasing the cost of the window 12, this additional layer itself may scratch and become damaged, thus obviating the benefits of the aluminum oxide layer itself.

The inventor recognized these additional problems of using aluminum oxide. Rather than taking the above noted, less desirable approach to solve this problem, the inventor discovered that if he appropriately textured the aluminum oxide surface, the protective layer 38 could substantially mitigate environmental reflections. In other words, by appropriately texturing the outside surface of the aluminum oxide protective layer 38, the window 12 can achieve both benefits—durability and anti-reflectiveness—in a cost effective manner.

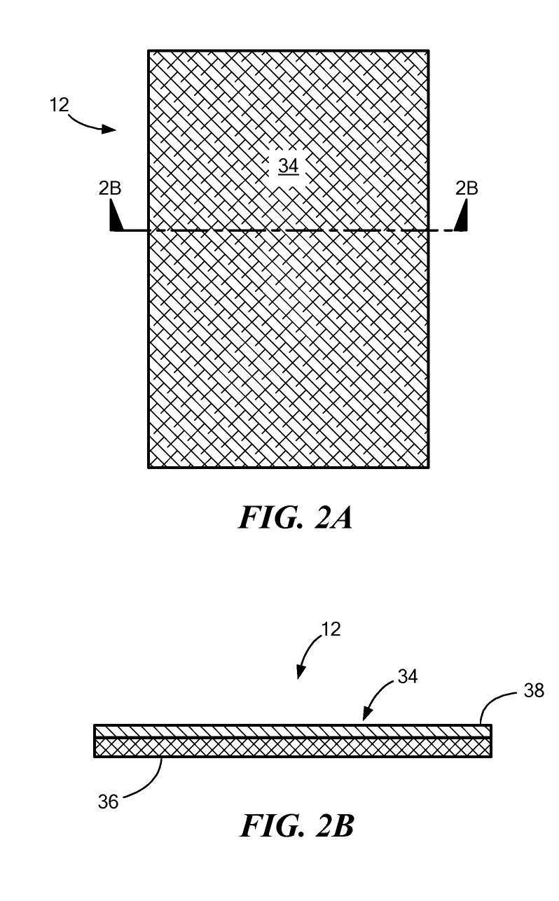

Accordingly, as shown in FIG. 2A, the top, environmentally exposed part of the protective layer 38 preferably forms a textured surface engineered to scatter light in a desired manner. Specifically, the top surface 34 preferably is configured to mitigate light reflections. A number of conventional processes can form this textured/roughened surface. FIG. 3 details one such exemplary process. Among other ways, the textures can be formed by conventional etching, photolithography, and/or deposition processes. As another example, carbon nanotube mats, nanowires, nanoparticles, or other films may be deposited in a specified manner to produce the desired surface.

Illustrative embodiments engineer the surface to have a root mean squared surface roughness (hereinafter “RMS,” as noted above) value that meets the requirements of the application—in the case of the device of FIG. 1A, to meet the needs of a smartphone 10. More specifically, as known by those in the art, characterization of surface topography is challenging because most surfaces have a distribution of asperities, ridges, pits and valleys, all of which may have variable shapes and dimensions. For this reason, the surface irregularities that form the surface texture may generally be characterized by some type of average. One common representation of surface roughness, RMS, averages the height deviation of N observed asperities Zi, from the mean, Z-bar:

$$RMS = {[ {\sum }_{i = 1}^{N} {( {Z}_{i} - Z \text{-} bar )}^{2} / ( N - 1 ) ]}^{0.5}$$

Since RMS is an averaged value, surfaces that have different irregularities may have the same RMS.

Standard roughness metrics like RMS are useful. However, as noted above, they generally do not fully characterize the surface features that affect anti-reflection properties. Accordingly, illustrative embodiments involve a class of surfaces which, at particular RMS values, exhibit beneficial anti-reflection properties.

More specifically, the minimum RMS surface roughness value can be selected as a function of the wavelength of the spectrum expected to pass through the window 12. In illustrative embodiments, this minimum RMS value is about 25 to 35 percent of the minimum wavelength of the preferred frequency range passing through the window 12. Stated another way, the textured surface preferably has features with dimensional scales that are on the approximate order of magnitude of about half of the wavelength of the lower end of the spectrum of interest. For example, for the visible spectrum (e.g., when used with the smartphone 10 of FIG. 1A), the textured surface can have a RMS surface roughness with a minimum value of about 100 nanometers, 150 nanometers, or 250 nanometers.

The electronics industry continually strives to reduce the weight and size of a wide variety of electronics devices. Accordingly, the window 12 preferably has a low mass and thickness. Those skilled in the art can select appropriate dimensions and thicknesses for the window 12 to meet those goals. To minimize reflection of light generated by the display portion 32 of the display 16, however, the face of the protective layer 38 preferably is spaced no more than about 1.0 to 1.5 millimeters from the face of the display portion 32. When this close and intimately coupled to the display portion 32, the protective layer 38 should only minimally scatter light directed outwardly toward the user. Accordingly, the substrate 36 preferably has a thickness of no greater than about 1.0 or 1.5 millimeters.

The protective layer 38, however, can be much thinner than that of the substrate 36. Those skilled in the art can select thickness based upon a number of factors. Specifically, a skilled artisan may choose the thickness to reduce weight and cost, maintain robustness, and ensure that the asperities, ridges, pits, and valleys of the textured surface do not penetrate all the way through the protective layer 38. For example, thicknesses of about 1 micron to 2 microns may suffice. Lower maximum thicknesses, such as about 300 to 500 nanometers, also may suffice. Of course, the etching process and specific etching material may have a bearing on the ultimate thickness. Preferably, only the top surface 34 of the protective layer 38 is affected by the etching step, while deeper portions of that layer 38 are not impacted.

It should be noted that, like other figures, FIGS. 1A-2B are schematic and not draw to scale. In addition, the components in those figures may have additional features that are not shown. Moreover, although a smartphone 10 is primarily discussed with regard to various embodiments, those skilled in the art can use the window 12 with any of a wide variety of other devices. For example, the window 12 may be used as part of a tablet computer, desktop computer, watch crystal, laptop computer, or consumer device electronics controlling a light source. Accordingly, discussion of the smartphone 10 is not intended to limit other embodiments.

As noted above, the window 12 may be formed using any of a wide variety of different processes. FIG. 3 shows one such process that may form the window 12 in accordance with illustrative embodiments of the invention. It should be noted that this process is substantially simplified from a longer process that normally would be used to form the window 12. Accordingly, the process of forming the window 12 may have many steps, such as testing steps, cutting steps, preparation steps, and post-processing steps that those skilled in the art likely would use. In addition, some of the steps may be performed in a different order than that shown, or at the same time. Those skilled in the art therefore can modify the process as appropriate.

Moreover, as noted above and below, many of the discussed materials and structures are but examples of a wide variety of different materials and structures that may be used. Those skilled in the art can select the appropriate materials and structures depending upon the application and other constraints. Accordingly, discussion of specific materials and structures is not intended to limit all embodiments.

The process of FIG. 3 may use bulk production techniques, which form a plurality of windows 12 from the same layered wafer/base at the same time. For example, a single sheet of materials having the layers shown in FIG. 2B can support a two dimensional array of windows 12 that ultimately are cut/separated by conventional processes at a later stage of the process. Although less efficient, however, those skilled in the art can apply these principles to a process that forms only one window 12.

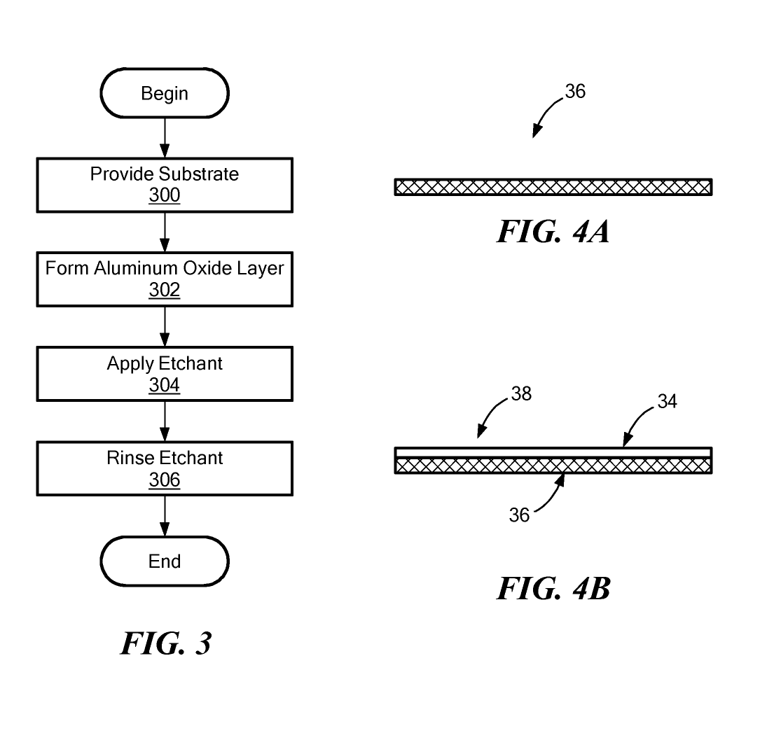

The process of FIG. 3 begins at step 300, which provides the optically transparent substrate 36. FIG. 4A schematically shows a cross-sectional view of the substrate 36 at this stage of the process. Next, step 302 forms the aluminum oxide protective layer 38 on the top surface of the substrate 36. In preferred embodiments, the aluminum oxide protective layer 38 is in a polycrystalline form conformably deposited as a thin film within a controlled environment, such as a deposition chamber. FIG. 4B schematically shows a cross-sectional view of the substrate 36 and protective layer 38 at this stage of the process. Specifically, at this stage of the process, the top surface 34 of the protective layer 38 is substantially smooth—particularly when compared to its final state (discussed below). Accordingly, the top surface 34 of the protective layer 38 has a relatively low RMS surface roughness.

In alternative embodiments, however, the aluminum oxide protective layer 38 may be a single crystal structure. In that case, the process may add additional defects/damage to the exposed surface of the aluminum oxide protective layer 38 after step 302. For example, the process may apply a high-energy ion source onto the surface. Alternatively, the process may dope or getter the surface, for example, using argon or hydrogen beams. As yet another example, the process may use laser ablation processes to produce raster defects across the surface, creating a pattern. As such, the protective layer 38 in this case may be considered to be “damaged” single-crystal aluminum oxide. In each case, the surface of the single crystal structure is processed so that it can be anisotropically etched in subsequent steps.

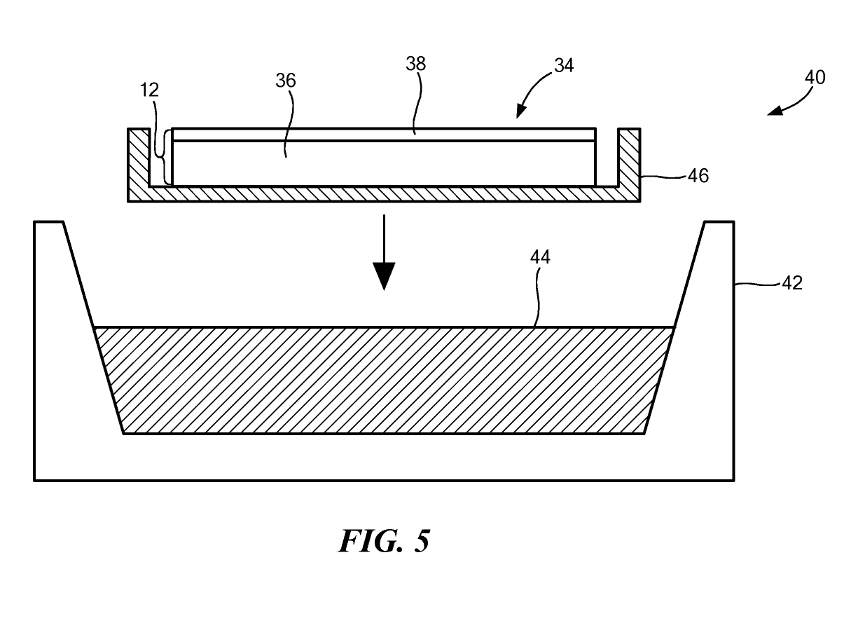

At this stage, the surface of the aluminum oxide protective layer 38 is generally planar and relatively smooth. Accordingly, step 304 applies etchant to the top surface 34 of the aluminum oxide protective layer 38 to produce a textured but still generally planar surface. To that end, FIG. 5 schematically shows a system 40 for etching the protective layer 38 in accordance with illustrative embodiments of the invention. The system 40 includes a bath 42 or other receptacle (containing an etchant 44) that receives the window 12 in its state as shown in FIG. 4B. Specifically, the bath 42 first receives the window 12 when the protective layer 38 is unetched and thus, relatively smooth.

Those skilled in the art select the etchant 44 to ensure that it forms the appropriately textured surface when exposed to the etchant 44. In addition, the etchant 44 preferably is selected so that it has no significant etching or other impact on the substrate 36. For example, if the substrate 36 is glass, then the etchant 44 may isotropically impact the substrate 36, but anisotropically etch the protective layer 38. Among other things, the etchant 44 may include an acid in liquid state, or a molten base (e.g., potassium hydroxide).

A conventional carrier 46 or other mechanism may lower the unetched window 12 into the bath 42, which may completely or partially cover the top surface 34 with the etchant 44. When in the bath 42, the etchant 44 non-uniformly attacks the top surface 34 at its surface defects. Specifically, those surface defects may include grain boundaries in the polycrystalline embodiment, and manufactured/damaged defects in the single crystal embodiment. The etchant 44 thus will produce the noted asperities, ridges, pits, valleys and other features that make up the textured surface. Accordingly, in both cases using either polycrystalline or single-crystalline aluminum oxide, the bath 42 preferably anisotropically etches the top surface 34 to produce the desired texture, which may be a random pattern across the surface.

After a predetermined time in the etchant 44 (e.g., five to ten minutes), the carrier 46 may move the window 12 upwardly, out of the bath 42, and then rinse remaining etchant 44 from the top surface 34 (step 306). At this point in the process, the protective layer 38 has a surface roughness similar to that shown in FIGS. 2A and 2B. More specifically, the surface of the protective layer 38 may have a RMS surface roughness that is much greater than that of the protective layer 38 before step 304 (i.e., greater than its nominal RMS surface roughness). For example, this process may have increased the RMS surface roughness of the protective layer 38 by more than ten times its original RMS surface roughness.

As noted, however, the bath 42 is but one of a wide variety of alternative techniques for texturing or roughening the surface of the protective layer 38. Accordingly, discussion of this specific process is illustrative and not intended to limit various embodiments of the invention.

Alternative embodiments eliminate the multi-layered window design. In that case, to both perform the protection and anti-glare functions, the window 12 has a single layer with a textured exterior facing surface. It has no substrate 36. This single layer window 12 preferably includes aluminum oxide, such as single-crystal sapphire. To etch the surface, the entire layer may be lowered into the etchant 44 contained by the bath 42, which etches all exposed surfaces. Other embodiments may lower just the top surface 34 into the bath 42 to etch only one of the two large planar surfaces. Indeed, other embodiments may etch the top surface 34 using other techniques.

Accordingly, illustrative embodiments overcome competing limitations to produce a window 12 that is both durable and antireflective. Use of aluminum oxide improves its cost effectiveness for use in lower cost devices, such as consumer devise like a smartphone or tablet.

Although the above discussion discloses various exemplary embodiments of the invention, it should be apparent that those skilled in the art can make various modifications that will achieve some of the advantages of the invention without departing from the true scope of the invention.

What is claimed is:

1. A window comprising:
a substantially optically transparent substrate; and
an aluminum oxide layer supported by the transparent substrate, the aluminum oxide layer having a textured surface.

2. The window as defined by claim 1 wherein the aluminum oxide layer comprises an anisotropically etched polycrystalline aluminum oxide.

3. The window as defined by claim 1 wherein the substrate has a top surface, the aluminum oxide layer comprising a film formed on the top surface of the substrate, the textured surface being opposite to that of the top surface of the substrate.

4. The window as defined by claim 1 wherein the substrate comprises one or more of glass, quartz, single-crystal sapphire, and yttria-stabilized zirconia.

5. The window as defined by claim 1 wherein the textured surface has an RMS surface roughness of at least 100 nanometers.

6. The window as defined by claim 1 wherein the aluminum oxide layer comprises an anisotropically etched damaged single-crystal sapphire.

7. The window as defined by claim 1 wherein the aluminum oxide comprises a film having a thickness of between about 300 nanometers and about 2 microns.

8. The window as defined by claim 1 wherein the aluminum oxide layer forms a planar surface textured to scatter at least a portion of light incident on the textured planar surface.

9. The window as defined by claim 1 wherein the aluminum oxide layer is hydrophobic.

10. A device comprising:
a light source;
a substantially optically transparent substrate; and
an aluminum oxide layer supported by the transparent substrate, the aluminum oxide layer having a textured surface.

11. The device as defined by claim 10 wherein the substrate is between the light source and the aluminum oxide layer, the aluminum oxide layer being no more than about 1.5 millimeters from the light source.

12. The device as defined by claim 10 further comprising smartphone, tablet computer, desktop computer, watch crystal, laptop computer, or consumer device electronics controlling the light source.

13. The device as defined by claim 10 wherein the light source comprises one or more of light emitting diodes or liquid crystals.

14. The device as defined by claim 10 wherein the aluminum oxide layer comprises an anisotropically etched polycrystalline sapphire.

15. The device as defined by claim 10 wherein the substrate has a top surface, the aluminum oxide layer comprising a film formed on the top surface of the substrate, the textured surface being opposite to that of the top surface of the substrate.

16. The device as defined by claim 10 wherein the substrate comprises one or more of glass, quartz, single-crystal sapphire, and yttria-stabilized zirconia.

17. The device as defined by claim 10 wherein the aluminum oxide layer comprises a film having a maximum thickness of between about 300 nanometers and about 2 microns.

18. The device as defined by claim 10 wherein the aluminum oxide layer forms a planar surface textured to scatter at least a portion of light incident on the textured planar surface.

19. A method of producing a window, the method comprising:
forming a layer of aluminum oxide on an optically transparent substrate;
covering at least a portion of the aluminum oxide layer in an etchant;
removing at least some of the etchant from the aluminum oxide layer, the aluminum oxide layer having a textured surface after removing at least some of the etchant.

20. The method as defined by claim 19 wherein covering comprises immersing at least the portion of the substrate and the aluminum oxide layer in a bath of the etchant.

21. The method as defined by claim 19 wherein removing comprises rinsing at least some of the etchant from the aluminum oxide layer.

22. The method as defined by claim 19 wherein the etchant comprises a base etchant.

23. The method as defined by claim 19 wherein the etchant anisotropically etches the aluminum oxide layer.
